(19) United States
(12) Patent Application Publication
(10) Pub. No.: US 2025/0308768 A1
(43) Pub. Date: Oct. 2, 2025

(54) COUPLER ARRANGEMENT

(71) Applicant: Infineon Technologies Austria AG, Villach (AT)

(72) Inventor: Matthias Stecher, München (DE)

(21) Appl. No.: 19/093,340

(22) Filed: Mar. 28, 2025

(30) Foreign Application Priority Data
Mar. 28, 2024 (EP) 24167494
Sep. 13, 2024 (DE) 102024126441.1

(51) Int. Cl. H01F 38/14; H01L 23/31; H01L 23/522; H10D 1/20; H10D 1/68

(52) U.S. Cl. CPC H01F 38/14; H01L 23/3171; H01L 23/5222; H01L 23/5227; H10D 1/20; H10D 1/692

(57) ABSTRACT

Disclosed is a coupler arrangement. The coupler arrangement includes a coupler having: a first planar conductor and a second planar conductor that are inductively or dielectrically coupled and spaced apart from each other in a first direction; an insulating layer above the first planar conductor; and a field plate layer above the insulating layer. The field plate layer is connected between a terminal of the first planar conductor and a reference terminal that is spaced apart from the first planar conductor.

### TECHNICAL FIELD

This disclosure relates in general to a coupler arrangement, such as a transformer arrangement or a capacitor arrangement.

### BACKGROUND

In many types of electronic circuits a galvanic decoupling (galvanic isolation) is required between electronic circuits or devices, such as between a control circuit and an electronic device or circuit controlled by the control circuit. A galvanic isolation may be used for safety reasons in order to prevent that a high-voltage occurring at the electronic circuit or device may occur at the control circuit. A galvanic isolation may also be used in those cases in which a reference potential of the electronic device or circuit is significantly different from a reference potential of the control circuit. The latter may occur, for example, in an electronic circuit in which the electronic device controlled by the control circuit is a high-side switch.

A galvanic isolation between electronic circuits can be achieved using a transformer, which may also be referred to as magnetic or inductive coupler, or a capacitor, which may also be referred to as capacitive coupler. The transformer includes a first winding and a second winding that is inductively coupled with the first winding. In a coreless transformer, the first and second windings are usually planar windings which may be arranged one above the other and which are electrically insulated from each other. Furthermore, a coreless transformer is devoid of a ferromagnetic core.

A signal transfer from the first winding to the second winding may include applying voltage pulses between first and second input terminals of the first winding. The voltage pulses applied to the first winding induce voltage pulses in the second winding, which can be detected at output terminals of the second winding.

During operation of the coupler arrangement surge pulses may occur between the first and second terminals of the first winding which may have a magnitude that is much higher than the magnitude of the voltage pulses during normal operation. Such surge pulses, which may result from lightning strikes in a network the transformer arrangement is connected to may damage the transformer arrangement.

Surge pulses are defined in IEC 61000-4-2, for example. Surge pulses as defined therein have a rise time of 1.2 microseconds (μs) and a falling half-life of 50 μs and may reach tens of kilovolts (kV). There is a need for a transformer arrangement with planar windings that is robust against surge pulses.

### SUMMARY

One example relates to a coupler arrangement. The coupler arrangement includes a coupler with a first planar conductor and a second planar conductor that are inductively or dielectrically coupled and spaced apart from each other in a first direction, an insulating layer formed above the first planar conductor, and a field plate layer formed above the insulating layer. The field plate layer is connected between a terminal of the first planar conductor and a reference terminal that is spaced apart from the first planar conductor.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 schematically illustrates a vertical cross-sectional view of a transformer arrangement having a transformer with a first winding (first coil) and a second winding (second coil) according to one example;

FIGS. 2A and 2B schematically illustrate horizontal cross-sectional views of the first winding and the second winding, respectively, of the transformer arrangement according to FIG. 1;

FIG. 3 schematically illustrates a modification of the transformer arrangement according to FIG. 1;

FIG. 4 illustrates a vertical cross-sectional view of one portion of the transistor arrangement according to FIG. 1;

FIG. 5 illustrates a vertical cross-sectional view of one portion of a transistor arrangement according to another example;

FIG. 6 illustrates equipotential lines that may occur in the transformer arrangement according to FIG. 5 when a surge pulse occurs;

FIG. 7 illustrates equipotential lines that may occur in a conventional transformer arrangement when a surge pulse occurs;

FIG. 8 illustrates one example of a transformer arrangement that includes a semiconductor body on top of which the transformer is arranged;

FIG. 9 illustrates one example of a transformer arrangement that includes two transformers;

FIGS. 10A and 10B illustrate horizontal cross-sectional views of the first windings and the second windings, respectively, of the two transformers illustrated in FIG. 9;

FIGS. 11A and 11B illustrate one example of an integrated circuit package that includes a transformer arrangement;

FIG. 12 illustrates an equivalent circuit diagram of the transformer arrangement according to FIGS. 11A and 11B;

FIG. 13 schematically illustrates a vertical cross-sectional view of a capacitive coupler arrangement having a capacitor with a first capacitor electrode and a second capacitor electrode according to one example;

FIGS. 14A and 14B schematically illustrate horizontal cross-sectional views of the first capacitor electrode and the second capacitor electrode, respectively, of the coupler arrangement according to FIG. 13; and

FIG. 15 schematically illustrates a modification of the capacitive coupler arrangement according to FIG. 13;

FIG. 16 illustrates an equivalent circuit diagram of an electronic circuit that includes a coupler arrangement with two capacitors; and

FIG. 17 illustrates an equivalent circuit diagram of an electronic circuit that includes a coupler arrangement with four capacitors.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

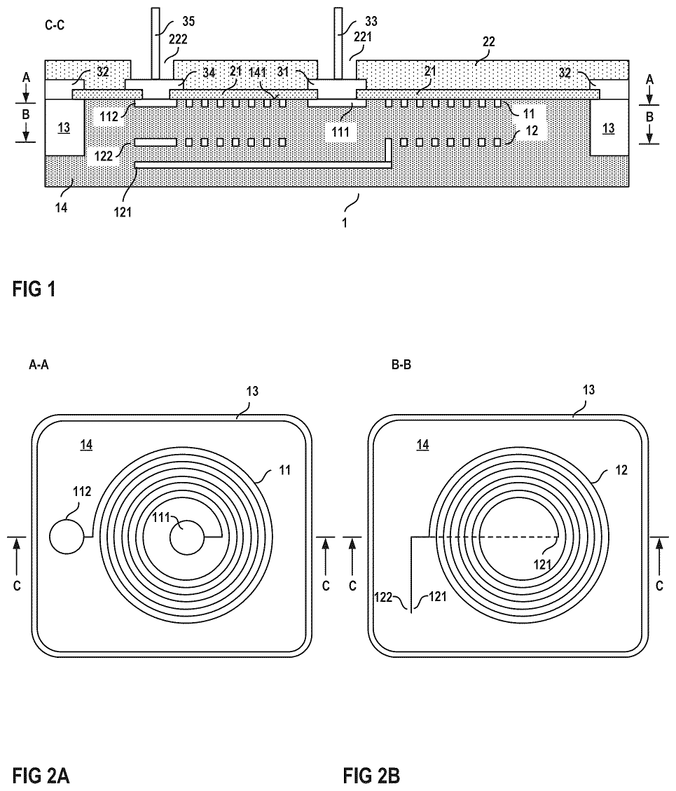

FIG. 1 schematically illustrates a vertical cross-sectional view of a transformer arrangement that is robust against surge pulses. The transformer arrangement includes a transformer 1 with a first winding (first coil) 11 and a second winding (second coil) 12 that are inductively coupled and that are spaced apart from each other in a first direction. FIG. 2A schematically illustrates a horizontal cross-sectional view of the first winding 11 in a first horizontal section plane A-A illustrated in FIG. 1, and FIG. 2B schematically illustrates a horizontal cross-sectional view of the second winding 12 in a second horizontal section plane B-B illustrated in FIG. 1. The vertical cross-sectional view illustrated in FIG. 1 is a cross-sectional view in a vertical section plane C-C illustrated in FIGS. 2A and 2B. The horizontal section planes A-A, B-B are essentially perpendicular to the first direction, and the vertical section plane C-C is essentially parallel to the first direction.

Referring to FIG. 1 and FIGS. 2A and 2B, each of the first winding 11 and the second winding 12 of the transformer 1 is a planar winding. That is, the first winding 11 is arranged essentially in a first horizontal plane and the second winding 12 is arranged essentially in a second horizontal plane. The first and second horizontal planes are essentially parallel and are spaced apart from each other in the first direction. In the example illustrated in FIG. 1 and FIGS. 2A and 2B, the first winding 11 is arranged above the second winding 12, so that the first winding 11 may also be referred to as to winding (top coil) and the second winding 12 may also be referred to as bottom winding (bottom coil).

Referring to FIG. 1, the transformer arrangement further includes an insulating layer 21 formed above the first winding 11, and a field plate layer 22 formed above the insulating layer 21. The field plate layer 22 is connected between a first terminal 111 of the first winding 11 and a reference terminal 13. The field plate layer 22 connected between the first terminal 111 of the first winding 11 and the reference terminal 13 helps to increase the robustness of the transformer arrangement against surge pulses that may occur, during operation of the transformer, between the first terminal 111 of the first winding 11 and the reference terminal 13. This is explained in detail herein further below.

According to one example, the insulating layer 21 includes a single electrically insulating layer. According to another example, the insulating layer 21 includes two or more electrically insulating sublayers arranged one above the other. According to one example, the insulating layer 21 includes a layer stack in which silicon nitride (SiN) and silicon dioxide (SiO₂) layers are alternatingly arranged one above the other.

The first and second windings 11, 12 are galvanically isolated from each other. The galvanic isolation between the first and second windings 11, 12 is achieved by arranging the first and second windings 11, 12 spaced apart from each other in the first direction, and by arranging electrically insulating material between the first and second windings 11, 12.

Referring to FIG. 1, the first and second windings 11, 12 may be arranged in a further insulating layer 14 that provides for the galvanic isolation and that may be referred to as interlayer dielectric. According to one example, the further insulating layer 14 includes at least one of an epoxy; an oxide, such as silicon oxide; a nitride, such as silicon nitride; and a ceramic, in particular a high-k ceramic, such as BaTiOx, AlOx, or the like. The further insulating layer 14 may include two or more insulating sublayers from the same electrically insulating material or from different electrically insulating materials. Forming the further insulating layer 40 with the first and second windings 11, 12 arranged therein may include forming a first portion of the further insulating layer 14, forming the second winding 12 in the first portion, forming a second portion of the further insulating layer 14 above the first portion and the second winding 12, and forming the first winding 11 in the second portion of the further insulating layer 14.

A distance between the first and second winding 17, 18 in the vertical direction is dependent on the dielectric strength of the material of the insulating layer 14 separating the first and second windings 17, 18 and a voltage applied between the first and second windings 17, 18. According to one example, the insulating layer 14 includes silicon oxide (SiO₂) and the distance is selected from between 7 micrometers (μm) and 30 micrometers, in particular between 15 micrometers and 20 micrometers.

In the following, the insulating layer 21 formed above the first winding 11 is also referred to as first insulating layer, and the further insulating layer 14, in which the first and second windings 11, 12 are embedded and that electrically insulates the first and second windings 11, 12 from each other, is also referred to as second insulating layer.

Referring to FIGS. 2A and 2B, each of the first and second windings 11, 12 includes a first end and a second end. In each case, the first end is an inner end of the respective winding 11, 12 and is arranged at a position that is surrounded by the individual turns of the respective winding 11, 12. The second end is an outer end of the respective winding 11, 12 and is arranged at a position outside the individual turns.

The inner end of the first winding 11 is connected to the first terminal 111 of the first winding 11, and the outer end of the first winding 11 is connected to a second terminal 112 of the first winding 11. Equivalently, the inner end of the second winding 12 is connected to a first terminal 121 of the second winding 12, and the outer end of the second winding 12 is connected to a second terminal 122 of the second winding 12. Each of the first and second terminals 111, 112, 121, 122 of the first and second windings 11, 12 is different from the reference terminal 13.

Referring to FIG. 1, the first and second terminals 121, 122 of the second winding 12 may be arranged one above the other, wherein the inner end of the second winding 12 may be connected to the first terminal 121 through a conductor 123 that extends below the winding from the inner end 121 the first terminal 121.

According to one example, the second terminal 122 of the second winding 12 and the reference terminal 13 are connected to the same circuit node. According to one example, this circuit node is a ground node of an electronic circuit in which the transformer circuit is arranged. In this example, the reference terminal 13 and the second terminal 122 of the second winding 12 at least approximately have the same electrical potential.

According to one example, the first and second terminals 111, 112 of the first winding 11 form an input of the transformer arrangement or are connected to an input of the transformer arrangement. The input is configured to receive a signal that is to be transmitted from the first winding 11 to the second winding 12. The signal to be transmitted may include a series of voltage pulses and/or current pulses. In this example, the first and second terminals 121, 122 of the second winding 12 form an output of the transformer arrangement or are connected to an output of the transformer arrangement. Due to the inductive coupling between the first and second windings 11, 12 voltage and/or current pulses applied to the first winding induce voltage and/or current pulses in the second winding 12 that can be detected at the first and second terminals 121, 122 of the second winding 12. According to another example, the first and second terminals 121, 122 of the second winding 2 form the input of the transformer arrangement and the first and second terminals 111, 112 of the first winding 11 form the output of the transformer arrangement. In each case, the signal can be transmitted wirelessly from the input of the transformer arrangement to the output of the transformer arrangement via the first and second windings 11, 12 that are galvanically isolated from each other. The first winding 11 is galvanically isolated from the reference terminal 13, while, as explained above, the second winding 12 may be connected to the reference terminal 13.

In the example illustrated in FIG. 1, the second winding 12 may be formed by forming a first portion of the second insulating layer 14 and forming the second winding 12 either on top of the first portion or in a trench in the first portion. The first winding 11 may be formed by forming a second portion of the second insulating layer 14 on top of the first portion and forming the first winding 11 either on top of the second portion or in a trench in the second portion. Just for the purpose of illustration, in the example illustrated in FIG. 1, the first winding 11 has been formed in a trench of the second insulating layer 14, so that the first winding 11 extends from a surface 141 of the second insulating layer 14 into the second insulating layer 14.

According to one example, the first insulating layer 21 is formed directly on top of the surface 141 of the second insulating layer 14 and covers the first winding 11. In the example illustrated in FIG. 1, in which the first winding 11 has been formed in a trench of the further insulating layer 14, the insulating layer 21 only covers a top surface of the first winding 11.

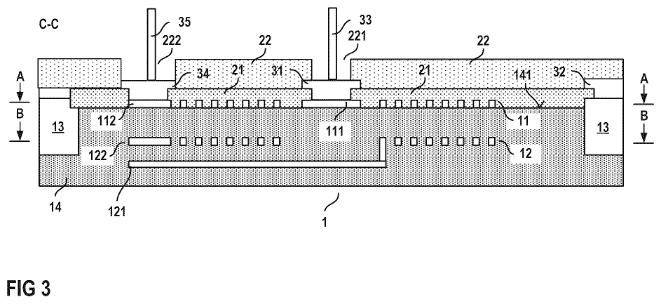

In another example illustrated in FIG. 3 in which the first winding 11 is formed on top of the second insulating layer 14, the first insulating layer 21 covers and partially embeds the first winding 11.

According to one example illustrated in FIGS. 2A and 2B, the reference terminal 13 laterally surrounds the first and second windings 11, 12. That is, the reference terminal 13 forms a closed loop around the first and second windings 11, 12 in lateral directions, which are directions that are essentially perpendicular to the first direction in which the first and second windings 11, 12 are spaced apart from each other. The closed loop formed by the reference terminal 13 has an essentially rectangular shape according to one example. The reference terminal 13 is spaced apart from each of the first and second windings 11, 12. The reference terminal 13 forming a closed loop around the first and second windings 11, 12 in lateral directions forms a guard ring of the transformer and is configured to prevent moisture and impurity ions from reaching sections inside the guard ring in which high electric fields may occur during operation of the transformer arrangement.

Referring to the above, the field plate layer 22 is electrically connected between the first terminal 111 of the first winding 11 and the reference terminal 13. For this, the field plate layer 22 may be connected to the first terminal 111 of the first winding 11 through a first contact 31 formed on top of the first terminal 111 and may be connected to the reference terminal 13 through a second contact 32 formed on top of the reference terminal 13. In the same way as the reference terminal 13, the second contact 32, according to one example, forms a closed loop around the first and second windings 11, 12. According to another example, the second contact 32 has a U-shape and contacts the reference terminal 13 forming a closed loop around the windings 11, 12 at three of the four side of the rectangular loop.

The first and second contacts 31, 32 may be formed after forming the first insulating layer 21, so that each of the first and second contacts 31, 32 may overlap the first insulating layer 21. The field plate layer 22 may be formed after forming the first and second contacts 31, 32 and cover the first insulating layer 21. Furthermore, the field plate layer 22 may partially overlap the first contact 31 and may partially overlap or entirely cover the second contact 32.

Referring to FIGS. 1 and 3, the field plate layer 22 may include a first contact opening 221 above the first contact 31. In the first contact opening 221 an electrical connector 33, such as a bond wire or the like, may be connected to the first contact 31. Furthermore, a second contact opening 222 may be formed in the field plate layer 22 above the second terminal 112 of the first winding 11 and a corresponding contact 34 that is electrically connected to the second terminal 112. In this example, the field plate layer 22 is connected to the contact 34, so that the field plate layer 22 is also connected to the second terminal 112 of the transformer 1.

As can be seen from FIG. 2A, the first terminal 111 may be located in a center of the first winding 11. The center of the first winding 11 is formed by an innermost turn of the first winding, wherein the first terminal 111 is connected to the innermost turn. The second terminal 112 may be located spaced apart from an outermost turn of the first winding 11 and is electrically connected to the outermost turn.

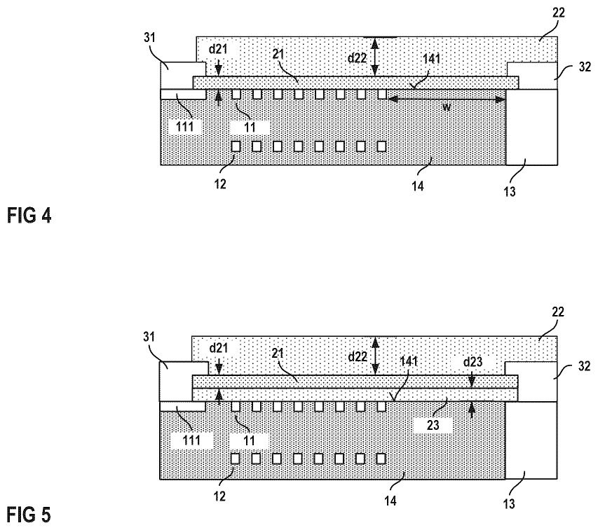

Details of the transformer arrangement according to one example are explained with reference to FIG. 4, which illustrates one portion of the transformer arrangement according to FIG. 1.

Referring to the above, the reference terminal 13 is spaced apart from each of the first and second windings 11, 12. According to one example a minimum distance between the first winding 11 and the reference terminal 13 in a lateral direction perpendicular to the first direction (in which the first and second windings 11, 12 are spaced apart from each other) is selected from between 150 micrometers and 250 micrometers. “Minimum distance” in this regard includes that there are portions of the first terminal 13 that are spaced apart from the winding 11 by the minimum distance. However, there may be further portions of the first terminal 13 that are further spaced apart from the winding 11 than the minimum distance.

According to one example, a thickness d21 of the first insulating layer 21 is selected from between 3 micrometers and 10 micrometers. The thickness d21 of the first insulating layer 21 is the dimension of the first insulating layer 21 in a direction that is essentially perpendicular to the first surface 141 of the second insulating layer 14 and that essentially equals the first direction in which the first and second windings 11, 12 are spaced apart from each other.

According to one example, the thickness d22 of the field plate layer 22 is selected from between 3 micrometers and 30 micrometers, in particular from between 10 micrometers and 20 micrometers. The thickness d22 of the field plate layer 22 is the dimension of the field plate layer 22 in a direction that is essentially perpendicular to the first surface 141 of the second insulating layer 14 and that essentially equals the first direction in which the first and second windings 11, 12 are spaced apart from each other.

The first insulating layer 21 includes an electrically insulating material. According to one example, the electrically insulating material is an oxide such as silicon oxide (SiO₂), a nitride such as silicon nitride (SiN), an imide, BCB (benzocyclobutene), or the like. According to one example, the first insulating layer 21 includes a layer stack with two or more of these insulating materials. According to one example, the layer stack includes a silicon dioxide (SiO₂) layer facing the surface 141 of the second insulating layer 14, and a silicon nitride (SiN) layer formed on top of the SiO₂ layer. In this layer stack, the SiN layer protects the SiO₂ layer and the transformer from moisture. The SiO₂ layer may be much thicker than the SiN layer and may have a thickness of between 3 μm and 10 μm. The thickness of the SiN layer is between 100 nanometers (nm) and 500 nm, for example.

Each of the first and second windings 11, 12 and the reference terminal 13 includes an electrically conducting material. Examples of the electrically conducting material include a metal, such as copper (Cu) or aluminum (Al), a metal alloy, a silicide, or a highly doped polysilicon.

The first and second contacts 31, 32 include an electrically conducting material. According to one example, the electrically conducting material includes a metal, such as copper (Cu) or aluminum (Al), or an alloy, such as a nickel-phosphorous alloy (NiP/Pd/Au) or a nickel-phosphorous-molybdenum alloy (NiMoP/Pd/Au).

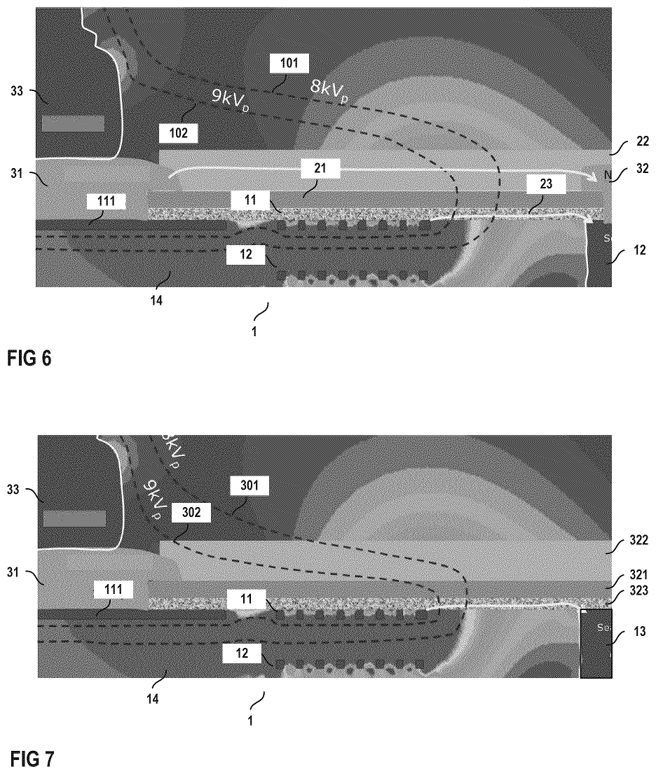

The field plate layer 22 includes a high resistivity material. The high resistivity of the field plate layer 22 provides for a high electrical resistance between the first terminal 111 and the reference terminal 13, so that even when a high voltage pulse occurs between the first terminal 111 and the reference terminal 13 only a very low leakage current can flow between the first terminal 111 and the reference terminal 13. According to one example, “high electrical resistance” includes an electrical resistance of more than 10 megaohm (MΩ), or even more than 100 megaohm (MΩ), so that the leakage current is lower than 1 nanoampere (nA) or even lower than 1 picoampere (pA). At the same time, an electrical potential of the field plate layer 22 ranges between the electrical potential of the first terminal 111 and the electrical potential of the first terminal 13. This helps to suitably shape the electric field in the first insulating layer 21 and the field plate layer 22 in the event of a surge pulse. This is explained with reference to FIG. 6 herein further below.

According to one example, the high resistivity material of the field plate layer 22 has a specific resistance of more than 1E10 Ω·μm (=1E14 Ω·cm) and less than 1E20 (2·cm), in particular, less than 1E19 Ω·cm. Examples of the high resistivity material include, but are not restricted to, a polyimide film such as kapton (specific resistance: about 1E17 Ω·cm), BCB, benzocyclobutene, (specific resistance: about 1E19 Ω·cm), polyimide (usually shortly referred to as imide), such as durimide 7520, (specific resistance: about 1E16 Ω·cm), silicone gel (specific resistance: about 1E15 Ω·cm).

FIG. 5 illustrates a further modification of the transformer arrangement according to claim 1. In the example illustrated in FIG. 5, the first insulating layer 21 is not directly formed on top of the second insulating layer 14 and the first winding 11. Instead, a passivation layer 23 is formed between the second insulating layer 14 and the first winding 11 on one side and the first insulating layer 21 on the other side. According to one example, the passivation layer 23 is configured to protect the first winding 11 against moisture. According to one example, the passivation layer 23 includes a nitride, such as silicon nitride (SiN). According to one example, the passivation layer 23 includes silicon nitride (SiN) or hydrogen doped silicon nitride (SiN:H).

According to one example, a thickness d23 of the passivation layer 23 is selected from between 0.1 micrometers and 3 micrometers. The thickness d23 of the passivation layer 23 is the dimension of the passivation layer 23 in a direction perpendicular to the surface 141 of the second insulating layer 14 and in the first direction in which the first and second windings 11, 12 are spaced apart from each other.

In the example illustrated in FIG. 5, the insulating layer 21 is formed above the passivation layer 23, and the field plate layer 22 is formed above the insulating layer 21. Everything explained above in context with the example illustrated in FIG. 4 regarding the insulating layer 21 and the passivation layer 22 applies to the example illustrated in FIG. 5 accordingly.

Referring to the above, the transformer arrangement can be used to transmit information from an input connected to the first and second terminals 111, 112 of the first winding 11 to the output connected to the first and second terminals 121, 122 of the second winding 12 or vice versa. Transmitting the information includes applying an input signal to be transmitted to the input and receiving an output signal that is dependent on the input signal at the output. The input signal includes the information to be transmitted. The output signal is dependent on the input signal, so that the transmitted information can be retrieved from the output signal.

The input signal may include voltage and/or current pulses, and the output signal available at the second winding 12 may include voltage and/or current pulses resulting from the voltage and/or current pulses applied to the first winding 11. A normal operating mode of the transformer arrangement is an operating mode in which a signal including information is transmitted from the first winding 11 to the second winding 12. Magnitudes of voltage pulses applied to the input of the transformer arrangement and, therefore, between the first and second terminals 111, 112 of the first winding 11 are lower than 10V or lower than 5V, for example. According to one example, magnitudes of the voltage pulses are 3.3 V or 1.2V.

In exceptional cases, high voltage pulses, which may also be referred to as surge pulses, may occur between the first terminal 111 and the reference terminal 13. An electrical potential of the reference terminal 13 is a ground potential of an electronic circuit in which the transformer arrangement is employed, for example. Surge pulses may result from lightning strikes, for example. Surge pulses may have a magnitude in the range of between 110V and 15 kV and may cause severe stress in the transformer 1, in particular, in the first insulating layer 21 and the field plate layer 22. “Surge pulse” as used herein, in particular, includes a high-current pulse between the first and second terminals 111, 112 of the first winding 11, which may result in a high-current pulse between the first and second terminals 121, 122 of the second winding 12, wherein the second winding 12, directly or indirectly, may be connected to the reference node 13. More specifically, the second winding 12, directly or indirectly, may be connected to same ground node the reference node 13 is connected thereto.

Connecting the field plate layer 22 between the first terminal 111 and the reference terminal 13 and, optionally between the second terminal 112 and the reference terminal 13 shapes the electric field associated with a surge pulse in such a way that maximum electric fields are reduced as compared to a conventional transformer arrangement. This is illustrated in FIGS. 6 and 7 and explained in the following.

FIG. 6 illustrates a portion of a transformer arrangement of the type illustrated in FIG. 5. The transformer arrangement illustrated in FIG. 6 includes the passivation layer 23. This passivation layer 23, however, is optional. That is, the effect explained in the following with reference to FIGS. 6 and 7 is not dependent on the presence of the passivation layer 23. FIG. 6 illustrates equipotential lines that may occur when a surge pulse with a magnitude of 10 kV is applied between the first terminal 111 and the reference terminal 13. Line 101 represents an electrical potential of 8 kV and line 102 represents an electrical potential of 9 kV. As commonly known, the electric field is particularly high in those regions in which equipotential lines are curved, wherein the lower the radius of the curvature the higher the electric field.

FIG. 7 illustrates a portion of a conventional transformer arrangement. In the transformer arrangement according to FIG. 7, the first transformer 1 is implemented in the same way as in the transformer arrangement according to FIG. 6, wherein like reference numbers denote like parts of the first transformer 1. The transformer arrangement according to FIG. 7 includes a passivation layer 323 on top of the second insulating layer 14 that separates the first and second winding 11, 12, a first insulating layer 321 on top of the passivation layer 323, and an imide layer on top of the first insulating layer 321. The imide layer 322 is connected to the first terminal 111 of the first winding 11, only, so that the electrical potential throughout the imide layer 322 equals the electrical potential at the first terminal 111.

FIG. 7 illustrates equipotential lines that may occur when a surge pulse with a magnitude of 10 kV is applied between the first terminal 111 and the reference terminal 13. Line 301 represents an electrical potential of 8 kV and line 302 represents an electrical potential of 9 kV.

As can be seen from FIGS. 6 and 7, curvatures of the equipotential lines 101, 102 in the transformer arrangement according to FIG. 6 have significantly larger radii than curvatures of the equipotential lines 301, 302 in the transformer arrangement according to FIG. 7. This is due to the field shaping effect of the field plate layer 22 connected between the first terminal 111 and the reference terminal 13 in the transformer arrangement according to FIG. 6. The higher radii of the curvatures of the equipotential lines in the transformer arrangement according to FIG. 6 result in lower electric fields in the transformer arrangement according to FIG. 6 as compared to the conventional transformer arrangement according to FIG. 7. The transformer arrangement according to FIG. 6 is therefore more robust against surge pulses than the transformer arrangement according to FIG. 7.

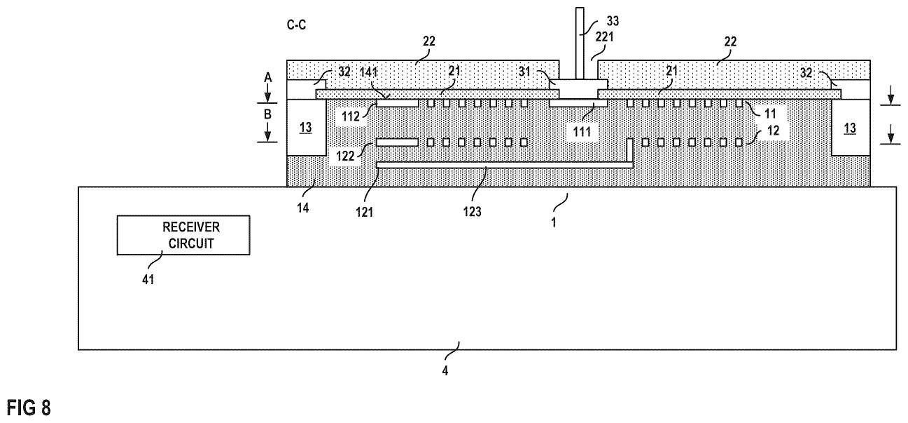

According to one example illustrated in FIG. 8, the second insulating layer 14 is arranged on top of a carrier 4. According to one example, the carrier 4 is a semiconductor body that includes an integrated receiver circuit 41, a transmitter circuit, both a receiver circuit and a transmitter circuit, or the like. The receiver circuit 41 is only schematically illustrated in FIG. 8. According to one example, the receiver circuit is connected to the first and second terminals 121, 122 of the second winding 12 in order to receive the voltage pulses and/or current pulses induced by the voltage pulses and/or current pulses applied to the first winding 11. The first and second terminals 121, 122 of the second winding 12 may be connected to the receiver circuit 41 in the semiconductor body 4 in a conventional way using electrically conducting vias, metallizations, and the like. This is commonly known, so that no further explanation is required in this regard.

According to one example, the receiver circuit 4 is configured to retrieve the information included in the input signal applied to the first winding 11 from the voltage pulses and/or current pulses received from the second winding 12. According to one example, the semiconductor body 4 is connected to a ground node, and the reference terminal 13 is connected to the same ground node.

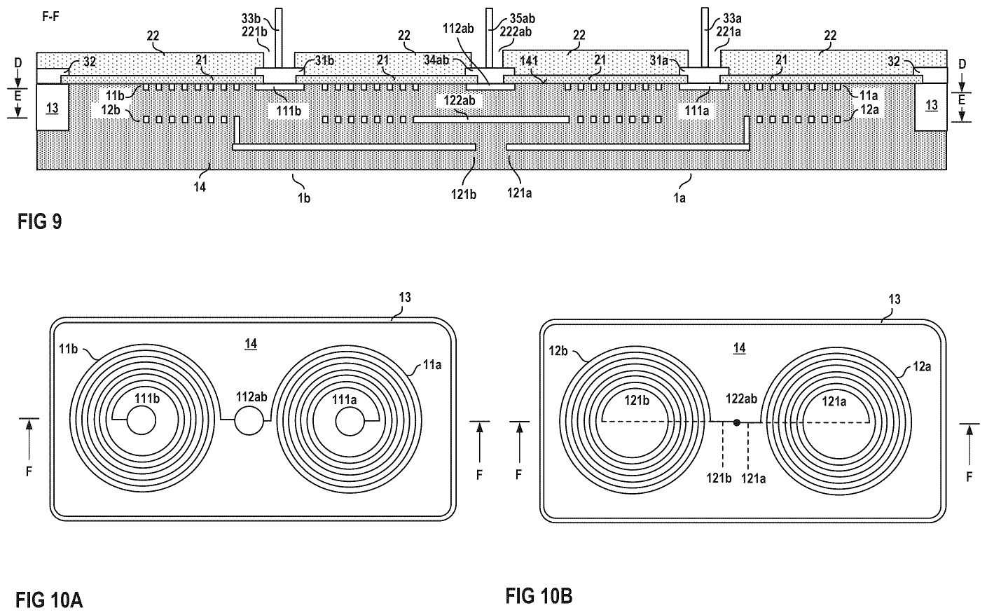

FIG. 9 and FIGS. 10A and 10B illustrate a transformer arrangement according to another example. This transformer arrangement includes two transformers 1a, 1b each having a first winding 11a, 11b and a second winding 12a, 12b. FIG. 9 shows a vertical cross-sectional view of the transformer arrangement, FIG. 10A shows a horizontal cross-sectional view of the first windings 11a, 11b, and FIG. 10B shows a horizontal cross-sectional view of the second windings 12a, 12b.

Everything explained with regard to implementing the transformer 1 explained herein before applies to implementing each of the first and second transformers 1a, 1b illustrated in FIG. 9 and FIGS. 10A and 10B accordingly. In FIG. 9 and in FIGS. 10A and 10B, features that correspond to the features of transformer 1 explained above have the same reference numbers, which are supplemented by an “a” in the case of the first transformer 1a and by a “b” in the case of the second transformer 1b.

The first and second transformers 1a, 1b are arranged in the same insulating layer 14. According to one example, the first windings 11a, 11b are arranged essentially in the same first horizontal plane of the insulating layer 14, and the second windings 12a, 12b are arranged essentially in the same second horizontal plane of the insulating layer 14. The first and second horizontal planes are planes that are essentially parallel to the surface 141 of the insulating layer 14. Furthermore, the first and second windings 11a, 11b, 12a, 12b are spaced apart from each other in a lateral direction, which is a direction that is essentially parallel to the first surface 141 of the insulating layer 14.

Each of the first windings 11a, 11b has a first terminal 111a, 111b that is located essentially in the center of the respective winding 11a, 11b. The second terminals of the first windings 11a, 11b are connected to form a common second terminal 112ab. Equivalently, each of the second windings 12a, 12b has a first terminal 121a, 121b that is located essentially in the center of the respective winding 12a, 12b. The second terminals of the second windings 12a, 12b are connected to form a common second terminal 122ab. The transformer arrangement with the two transformers 1a, 1b that have the second terminals 112ab of the first windings 11b, 11b and the second terminals 122ab of the second windings 12a, 12b connected may be used for a differential signal transmission.

Referring to FIG. 9 and FIGS. 10A and 10B the reference terminal 13 surrounds both the first transformer 1a and the second transformer 1b. The field plate layer 22 that is formed on top of the insulating layer 21 is connected to the reference terminal 13 and is connected to both the first terminal 111a of the first transformer 1a and the first terminal 111b of the second transformer 11b. Furthermore, in this example, the field plate layer 22 is connected to the common second terminal 112ab of the first windings 11a, 11b. For this, the field plate layer 22 is connected to common second terminal 112ab through an electrically conducting contact 34ab. Referring to FIG. 9, the field plate layer 22 includes openings 221a, 221b above the first terminals 111a, 111b of the first windings 11a, 11b and an opening 222ab above the common second terminal 112ab of the first windings 11a, 11b. In these openings 221a, 221b, 222ab the respective contacts 31a, 31b, 34ab may be connected to a conductor 33a, 33b, 35ab, such as a bond wire.

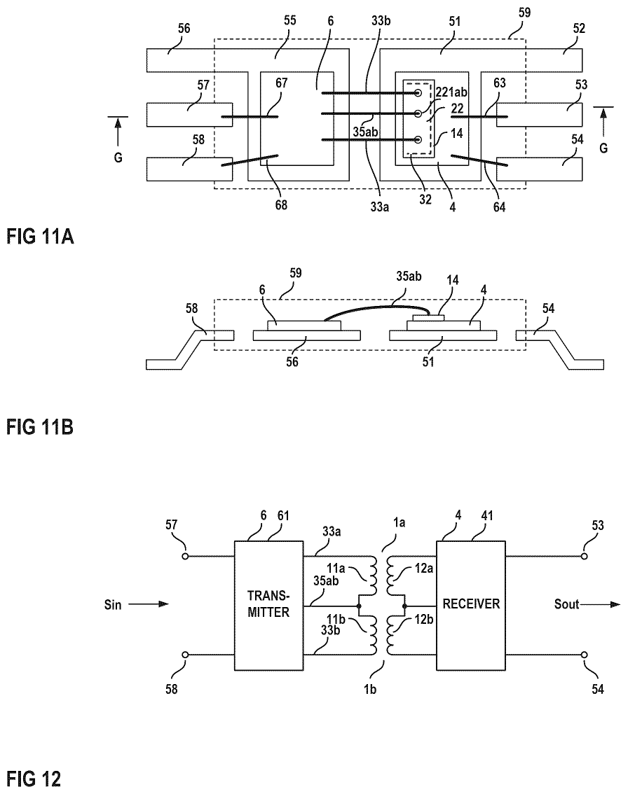

Each of the transformer arrangements explained herein before can be integrated in an integrated circuit package. FIGS. 11A and 11B illustrate one example of an integrated circuit package that includes a transformer arrangement of the type illustrated in FIG. 9, wherein the insulating layer 14 with the first and second transformers 1a, 1b is arranged above a semiconductor body 4 that includes a receiver circuit. FIG. 11A shows a top view of the integrated circuit package, and FIG. 11B shows a vertical cross-sectional view.

The integrated circuit package includes a first carrier 51 on top of which the semiconductor body 4 with the insulating layer 14 including the first and second transformers 1a, 1b is arranged. The first carrier 51 with the semiconductor body 4 and the insulating layer 14 including the first and second transformers 1a, 1b is arranged in a housing 59 such as, for example, a mold compound. The first carrier 51 may include an electrically conducting leg 52, which may also be referred to as pin. The pin 52 protrudes from the housing 59 and makes it possible to connect the surface of the semiconductor body 4 mounted to the first carrier 51 to a predefined electrical potential.

Referring to the above, a receiver circuit (not illustrated in FIG. 11A) may be integrated in the semiconductor body 4. In this example, output nodes of the receiver circuit may be connected by conductors 63, 64 to electrically conducting pins 53, 54 that protrude from the housing 59. The conductors 63, 64 are bond wires, for example. The pins 53, 54 form output nodes (output pins) of the transformer arrangement, which are accessible from outside the housing 59.

According to one example, a transmitter circuit integrated in a further semiconductor body 6 is arranged in the same integrated circuit package. Referring to FIGS. 11A and 11B, the further semiconductor body 6 with the transmitter circuit is arranged on a second carrier 55. The second carrier 55 may include an electrically conducting pin 56 that protrudes from the housing 59 and makes it possible to electrically connect the further semiconductor body 6 to a predefined electrical potential. The transmitter circuit may include input nodes that are connected to electrically conducting pins 57, 58 by conductors 67, 68. The pins 57, 58 form input nodes (input pins) of the transformer arrangement, which are accessible from outside the housing 59. The conductors 67, 68 are bond wires, for example.

The transmitter circuit integrated in the further semiconductor body 6 is electrically connected to the first and second transformers via the conductors 33, 33b, 35ab.

It should be noted that the integrated circuit package may include further electrically conducting pins such as pins for providing supply voltages to the transmitter and the receiver circuit. Such electrical conducting pins, however, are not illustrated in FIGS. 11A and 11B. Furthermore, it should be noted that the semiconductor bodies 4, 6 are not restricted to have transmitter and receiver circuit is integrated therein. Instead, further electronic circuits such as analog-to-digital converters (ADCs), digital-to-analog converters (DACs), gate drivers, sensors, or the like may be integrated in the semiconductor bodies 4, 6 as well.

Referring to the above, the reference terminal 13 may be connected to the field plate layer 21 through a contact 32. As explained above, the contact 32 may form a closed loop in the same way as the reference terminal 13 or may have a U-shape. In the example illustrated in FIG. 11A, the reference terminal 13 is not illustrated, but the shape of the contact 32 is illustrated in dashed lines. In this example, the contact 32 has a U-shape and is arranged such that it is not located below the conductors 33, 33b, 35ab. The conductors 33, 33b, 35ab may also have a field shaping effect, so that an electrical connection between the reference terminal 13 and the field plate layer 21 may not be required in a region below the conductors 33, 33b, 35ab.

It should be noted that, in the arrangement illustrated in FIGS. 11A-11B, forming the first and second transformers above the semiconductor body 4 in which the receiver (not illustrated in FIGS. 11A-11B) is integrated is only an example. According to another example, the first and second transformers are formed above the further semiconductor body 6 which may include a transmitter circuit.

FIG. 12 shows an equivalent circuit diagram of the transformer arrangement integrated in the integrated circuit package according to FIGS. 11A and 11B. Referring to FIG. 12, the transformer arrangement included in the integrated circuit package includes a transmitter 61 in the further semiconductor body 6, wherein the transmitter 61 is configured to receive an input signal Sin via the input pins 57, 58. The transmitter is connected to the first windings 11a, 11b of the first and second transformers 1a, 1b. The transformer arrangement further includes the receiver 41 that is connected to the second windings 12a, 12b of the first and second transformers 1a, 1b and is configured to provide an output signal Sout at the output pins 53, 54. The transmitter 61 is configured to apply voltage and/or current pulses to the first windings 11a, 11b that are dependent on the input signal Sin. The voltage and/or current pulses applied to the first windings 11a, 11b induce corresponding voltage and/or current pulses in the second windings 12a, 12b. The voltage and/or current pulses induced in the second windings 12a, 12b are detected by the receiver 41 that is configured to generate the output signal Sout dependent on the detected voltage and/or current pulses.

The transformer arrangement explained herein before is one example of an inductive coupler arrangement. In this transformer arrangement, the first planar winding 11 is a first planar conductor and the second planar winding 12 is a second planar conductor of the transformer arrangement.

It should be noted that a coupler arrangement with a field plate layer 22 of the type explained herein above is not restricted to be implemented as a transformer arrangement with a first winding 11 and a second winding 21. According to another example, the coupler arrangement is implemented as a capacitive coupler arrangement (or capacitor arrangement) that includes a capacitor 7 instead of the transformer 1 explained herein above.

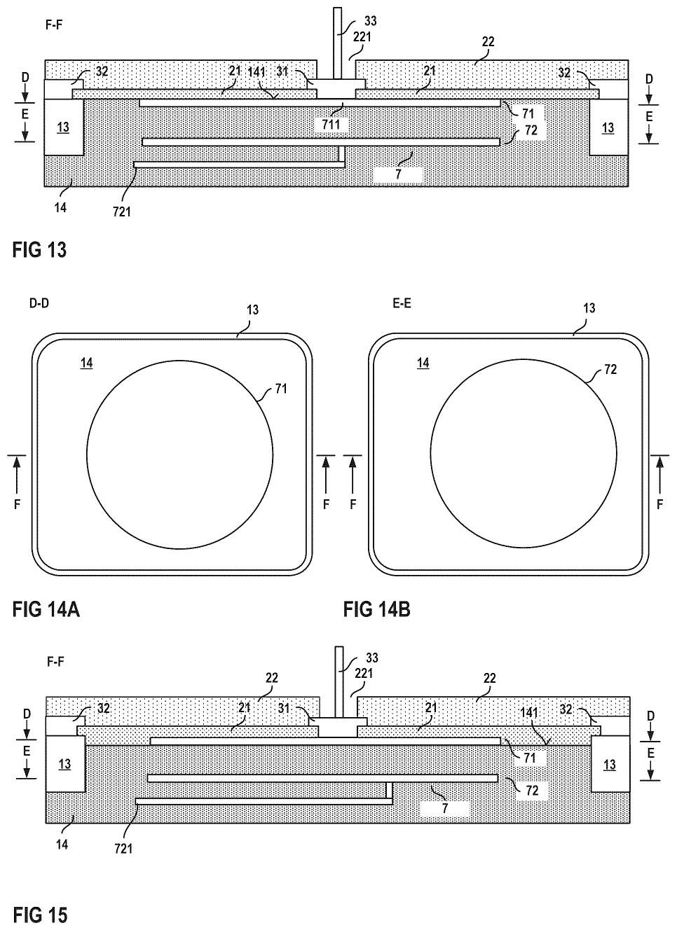

FIG. 13 illustrates a vertical cross-sectional view of a capacitive coupler arrangement according to one example. The capacitive coupler arrangement illustrated in FIG. 13 is based on the transformer arrangement according to FIG. 1 and is different from the transformer arrangement according to FIG. 1 in that it includes a capacitor 7 instead of the transformer 1. More specifically, the first winding 11 forming a first planar conductor of the transformer 1 is replaced by a first planar capacitor electrode 71 and the second winding 21 forming a second planar conductor of the transformer arrangement is replaced by a second planar capacitor electrode 72. The first planar capacitor electrode 71 forms a first planar conductor of the capacitor 7, and the second planar capacitor electrode 72 to forms a second planar conductor of the capacitor.

The first and second capacitor electrodes 71, 72 are spaced apart from each other in the first direction and are dielectrically coupled with each other. In the example illustrated in FIG. 13, the first and second capacitor electrodes are dielectrically coupled by the insulating layer 14, which is a dielectrically insulating layer in this example.

Instead of two terminals of the first and second windings 11, 21, each of the first and second capacitor electrodes 71, 72 only includes one terminal 711, 721 that corresponds to the first terminals 111, 121 of the first and second windings 11, 21 of the transformer arrangement. The field plate layer 22 is coupled between the terminal 711 of the first capacitor electrode 71 and the reference terminal 13.

FIG. 14A shows a horizontal cross-sectional view of the first capacitor electrode 71 according to one example, and FIG. 14B shows a horizontal cross-sectional view of the second capacitor electrode 72 according to example. In the examples illustrated in FIGS. 14A and 14B the first and second capacitor electrodes 71, 72 are circular. This, however, is only an example. According to another example, not illustrated, the first and second capacitor electrodes 71, 72 are rectangular.

In the example illustrated in FIG. 13, the first and second capacitor electrodes 71, 72 are embedded in the insulating layer 14. This, however, is only an example. According to another example illustrated in FIG. 15, the second capacitor electrodes 72 is embedded in the insulating layer 14 and the first capacitor electrode 71 is formed on top of the insulating layer 14. The capacitive coupler arrangement according to FIG. 15 is based on the transformer arrangement according to FIG. 3, wherein the first and second windings 11, 12 are replaced by the first and second planar capacitor electrodes 71, 72.

Everything explained hereinabove with regard to arranging the first and second windings 11, 12 relative to each other and relative to other parts of the transformer arrangement applies to arranging the first and second capacitor electrodes 71, 72 relative to each other and relative to other parts of the capacitor arrangement accordingly. Furthermore, everything explained hereinabove with regard to the field plate layer 22 and the reference terminal 13 of the transformer arrangement applies to the field plate layer 22 and the reference terminal 13 in the capacitive coupler arrangement accordingly.

Similar to a coupler arrangement including two transformers 1a, 1b one example of the capacitive coupler arrangement includes two capacitors 7a, 7b. For this, in the example illustrated in FIG. 9, for example, the first and second transformers 1a, 1b may be replaced by first and second capacitors 7a, 7b.

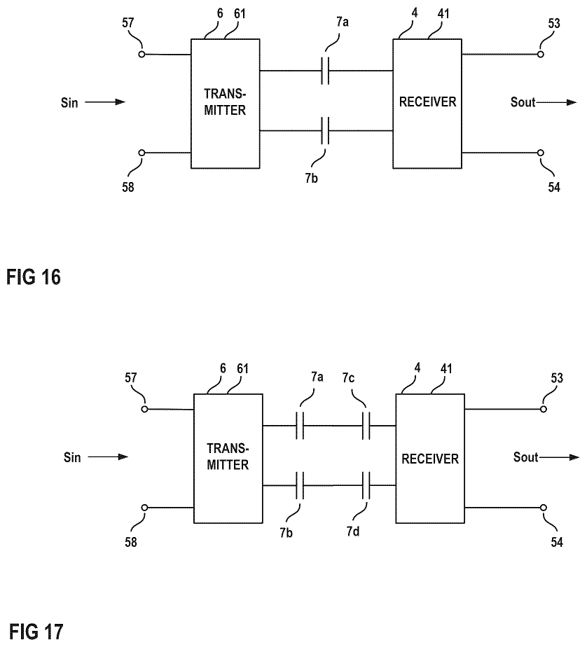

FIG. 16 illustrates an equivalent circuit diagram of an electronic circuit that includes a coupler arrangement with two capacitors 7a, 7b. The example illustrated in FIG. 16 is based on the example illustrated in FIG. 12 and includes two capacitors that are each connected between the transmitter 61 and the receiver 41. More specifically, each of the first and second capacitors 7a, 7b has its respective first capacitor electrode connected to the transmitter 61 and its respective second capacitor electrode connected to the receiver 41.

Each of the two capacitors 7A, 7B illustrated in FIG. 16 can be implemented in accordance with any of the examples illustrated in FIGS. 13, 14A-14B, and 15. Similar to the first and second transformers 1a, 1b illustrated in FIGS. 9 and 10A-10B, the first and second capacitors 7A, 7B can be implemented such that they are arranged next to each other and are both surrounded by the same guard ring 13.

The electronic circuit illustrated in FIG. 16 may be implemented similar to the electronic circuit illustrated in FIGS. 11A-11B. The first and second capacitors 7a, 7b may be formed above the semiconductor body that includes the receiver, such as semiconductor body 4 illustrated in FIG. 11A, or may be formed above the semiconductor body that includes the transmitter, such as semiconductor body 6 illustrated in FIG. 11A.

Methods for signal communication from a transmitter, such as transmitter 61 illustrated in FIG. 16, to a receiver, such as receiver 41 illustrated in FIG. 16, or vice versa, across two capacitors, such as capacitors 7a, 7b illustrated in FIG. 16, are commonly known, so that no further explanation is required in this regard.

FIG. 17 shows a modification of the electronic circuit according to FIG. 16. The electronic circuit according to FIG. 17 is different from the electronic circuit according to FIG. 16 in that it additionally includes a third capacitor 7c connected between the first capacitor 7a and the receiver 41, so that the first capacitor 7a and the third capacitor 7c are connected in series between the transmitter 61 and the receiver 41. Furthermore, the electronic circuit includes a fourth capacitor 7d connected between the second capacitor 7b and the receiver 41, so that the second capacitor 7b and the fourth capacitor 7d are connected in series between the transmitter 61 and the receiver 41. This type of electronic circuit, the maximum voltage across each of the capacitors is reduced to about 50% of the maximum voltage that may occur across each of the first and second capacitors 7a, 7b in the electronic circuit according to FIG. 16.

The electronic circuit illustrated in FIG. 17 may be implemented similar to the electronic circuit illustrated in FIGS. 11A-11B. According to one example, the first and second capacitors 7a, 7b are formed above the semiconductor body that includes the transmitter 41, such as semiconductor body 4 illustrated in FIG. 11A, and the third and fourth capacitors 7c, 7d are formed above the semiconductor body that includes the receiver 61, such as semiconductor body 6 illustrated in FIG. 11A.

Some of the examples explained above are briefly summarized in the following with reference to numbered examples.

Example 1. A coupler arrangement, comprising: a coupler comprising a first planar conductor and a second planar conductor that are inductively or dielectrically coupled and spaced apart from each other in a first direction; an insulating layer formed above the first planar conductor; and a field plate layer formed above the insulating layer, wherein field plate layer is connected between a terminal of the first planar conductor and a reference terminal that is spaced apart from the first planar conductor.

Example 2. The coupler arrangement of claim 1, wherein the field plate layer comprises a material with a specific resistance of more than 1E14 Ω·cm.

Example 3. The coupler arrangement of claim 1 or 2, wherein the material of the field plate layer comprises at least one of a polyimide film, BCB, polyimide, and silicone gel.

Example 4. The coupler arrangement of claim 1 or 2, wherein the terminal of the first planar conductor is arranged in a center of the first planar conductor and the reference terminal surrounds the first planar conductor.

Example 5. The coupler arrangement of any one of the preceding claims, further comprising: a passivation layer arranged between the insulating layer and the first planar conductor.

Example 6. The coupler arrangement of claim 5, wherein the passivation layer comprises silicon nitride, silicon carbide (SiC), silicon rich silicon nitride (SiN), silicon nitride (SiN), or hydrogen doped silicon nitride (SiN:H).

Example 7. The coupler arrangement of any one of the preceding claims, wherein the terminal is connected to the field plate layer through an electrical contact.

Example 8. The coupler arrangement of any one of the preceding claims, wherein the field plate layer is connected to the reference terminal through a further electrical contact.

Example 9. The coupler arrangement of claim 8, wherein an electrical connector is connected to the terminal, wherein the electrical connector extends beyond the reference terminal, and wherein the coupler arrangement is devoid of the further electrical contact in a region between the connector and the reference terminal.

Example 10. The coupler arrangement of any one of claims 7 to 9, wherein the electrical contact comprises a nickel-phosphorous alloy.

Example 11. The coupler arrangement of any one of the preceding claims, wherein a thickness of the field plate layer is selected from between 3 micrometers and 30 micrometers.

Example 12. The coupler arrangement of any one of the preceding claims, wherein a distance between the first winding and the reference terminal is selected from between 30 micrometers and 250 micrometers.

Example 13. The coupler arrangement of any one of claims 1 to 12, wherein the coupler is a transformer, wherein the first planar conductor is a first winding of the transformer and further comprises a second terminal different from the first terminal and the reference terminal; and wherein the second planar conductor is a second winding of the transformer.

Example 14. The coupler arrangement of any one of claims 1 to 13, wherein the coupler is a capacitor; wherein the first planar conductor is a first capacitor electrode of a capacitor; and wherein the second planar conductor is a second capacitor electrode of the capacitor.

Example 15. The coupler arrangement of claim 13 or 14, further comprising: a carrier on top of which the coupler is arranged.

Example 16. The coupler arrangement of claim 15, wherein the carrier comprises a semiconductor body, and wherein the coupler arrangement further comprises an integrated circuit arranged in the semiconductor body and connected to the second planar winding of the transformer.

Example 17. The coupler arrangement of claim 16, wherein the reference terminal is electrically connected to a reference node of the semiconductor body.

Example 18. The coupler arrangement of any one of the preceding claims, wherein the coupler is a first coupler, wherein the coupler arrangement further comprises a second coupler, wherein each of first coupler and the second coupler has a respective terminal, wherein the field plate layer is connected to the terminal of the first coupler and the second coupler.

Example 19. The coupler arrangement of claim 18, wherein the reference terminal at least partially surrounds a first planar conductor of the first coupler and a second planar conductor of the second coupler.

Example 20. The coupler arrangement of claim 18 or 19, wherein the first coupler and the second coupler are a first transformer and a second transformer that have a common further terminal.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A coupler arrangement, comprising:
a coupler comprising a first planar conductor and a second planar conductor inductively or dielectrically coupled and spaced apart from each other in a first direction;
an insulating layer above the first planar conductor; and
a field plate layer above the insulating layer,
wherein the field plate layer is connected between a terminal of the first planar conductor and a reference terminal that is spaced apart from the first planar conductor.

2. The coupler arrangement of claim 1, wherein the field plate layer comprises a material with a specific resistance of more than 1E14 Ω·cm.

3. The coupler arrangement of claim 2, wherein the material of the field plate layer comprises at least one of a polyimide film, BCB, polyimide, and silicone gel.

4. The coupler arrangement of claim 1, wherein the terminal of the first planar conductor is arranged in a center of the first planar conductor, and wherein the reference terminal surrounds the first planar conductor.

5. The coupler arrangement of claim 1, further comprising:
a passivation layer between the insulating layer and the first planar conductor.

6. The coupler arrangement of claim 5, wherein the passivation layer comprises silicon nitride, silicon carbide, silicon rich silicon nitride, or hydrogen doped silicon nitride.

7. The coupler arrangement of claim 1, wherein the terminal of the first planar conductor is connected to the field plate layer through an electrical contact.

8. The coupler arrangement of claim 7, wherein the field plate layer is connected to the reference terminal through a further electrical contact.

9. The coupler arrangement of claim 8, wherein an electrical connector is connected to the terminal of the first planar conductor, wherein the electrical connector extends beyond the reference terminal, and wherein the further electrical contact is omitted from a region between the electrical connector and the reference terminal.

10. The coupler arrangement of claim 7, wherein the electrical contact comprises a nickel-phosphorous alloy.

11. The coupler arrangement of claim 1, wherein a thickness of the field plate layer is between 3 micrometers and 30 micrometers.

12. The coupler arrangement of claim 1, wherein a distance between the first winding and the reference terminal is between 30 micrometers and 250 micrometers.

13. The coupler arrangement of claim 1, wherein the coupler is a transformer, wherein the first planar conductor is a first winding of the transformer and further comprises a second terminal different from the first terminal and the reference terminal, and wherein the second planar conductor is a second winding of the transformer.

14. The coupler arrangement of claim 1, wherein the coupler is a capacitor, wherein the first planar conductor is a first capacitor electrode of the capacitor, and wherein the second planar conductor is a second capacitor electrode of the capacitor.

15. The coupler arrangement of claim 1, further comprising:
a carrier on top of which the coupler is arranged.

16. The coupler arrangement of claim 15, wherein the coupler is a transformer, wherein the first planar conductor is a first winding of the transformer and further comprises a second terminal different from the first terminal and the reference terminal, wherein the second planar conductor is a second winding of the transformer, wherein the carrier comprises a semiconductor body, and wherein an integrated circuit is arranged in the semiconductor body and connected to the second winding of the transformer.

17. The coupler arrangement of claim 16, wherein the reference terminal is electrically connected to a reference node of the semiconductor body.

18. The coupler arrangement of claim 1, further comprising:
an additional second coupler,
wherein the coupler and the additional coupler each have a respective terminal,
wherein the field plate layer is connected to the terminal of the coupler and the terminal of the additional coupler.

19. The coupler arrangement of claim 18, wherein the reference terminal at least partially surrounds a first planar conductor of the coupler and a second planar conductor of the additional coupler.

20. The coupler arrangement of claim 18, wherein the coupler is a first transformer, wherein the additional coupler is a second transformer, and wherein the first transformer and the second transformer have a common further terminal.
